(19) United States
(12) Patent Application Publication
(10) Pub. No.: US 2023/0003996 A1
(43) Pub. Date: Jan. 5, 2023

(54) MEMS DEVICE AND METHOD OF DRIVING MEMS DEVICE

(71) Applicant: SONY GROUP CORPORATION, TOKYO (JP)

(72) Inventor: TOMOKI ONO, Tokyo (JP)

(21) Appl. No.: 17/756,881

(22) PCT Filed: Dec. 10, 2020
(86) PCT No.: PCT/JP2020/046026

§ 371 Date: Jun. 3, 2022

(30) Foreign Application Priority Data
Dec. 17, 2019 (JP) 2019-226938

(51) Int. Cl. G02B 26/08; B81B 5/00

(52) U.S. Cl. CPC G02B 26/0858; B81B 5/00; B81B 2201/042; B81B 2203/06

(57) ABSTRACT

A MEMS device includes: a first beam and a second beam that are symmetrically disposed with respect to a first rotation axis of a mirror portion, in which a third beam is disposed on a side opposite to the first beam and the second beam with reference to a line that is orthogonal to the first rotation axis and passes through a center of gravity of the mirror portion.

### BACKGROUND ART

A MEMS (Micro Electro Mechanical Systems) mirror is an optical device using a mirror having a diameter of a sub-millimeter to ten and several millimeters, and is used in an optical sensor, optical communication, optical computing, a projection device, and the like. In particular, the optical scanning method in which the mirror twists and vibrates has a simple structure and high durability, and thus has been continuously developed. The performance of such a MEMS mirror is evaluated by a figure of merit θdf using an optical swing angle θ degree, a mirror diameter d mm, and a resonant frequency f kilohertz in some cases, and generally, the larger the figure of merit θdf, the higher the performance of the application. For example, in a projector, the larger the optical swing angle θ, the smaller the slow ratio, the larger the mirror diameter d, the higher the condensing property of the irradiation beam and the clearer the image, and the larger the resonant frequency f, the higher the resolution. In a distance sensor, the larger θ is, the wider the detection region, the larger the mirror diameter d, the detection sensitivity is improved because the efficiency of taking in scatted light from an object, and the larger the resonant frequency f, the more detection points are.

As a method of increasing the figure of merit θdf, a coupled vibration structure (see, for example, Non-Patent Literature 1), a structure in which an action point is provided outside an axis (see, for example, Patent Literature 1), and the like have been proposed. The coupled vibration structure requires a large dead space because a counterweight is provided around the mirror. Further, the structure in which an action point is provided outside an axis requires a large dead space particularly in the case where a twisting operation of two axes is necessary, because of the large vibration input unit. These dead spaces restrict the optical path of the laser incident on the MEMS mirror and the optical path of the reflected laser, which causes problems that the system performance is deteriorated and the system size increases.

### CITATION LIST

### Patent Literature

Patent Literature 1: Japanese Patent Application Laid-open No. 2005-148459

### Non-Patent Literature

Non-Patent Literature 1: Utku Baran, et al. “Resonant PZT MEMS Scanner for High-Resolution Displays” Journal of microelectromechanical systems, Vol. 21, No. 6, p.1303, December 2012

### DISCLOSURE OF INVENTION

### Technical Problem

As described above, in the existing MEMS mirror, the dead space becomes larger as the figure of merit increases. It is an object of the present disclosure to provide a MEMS device that realizes both an improvement of the figure of merit of the MEMS device and a decrease in the dead space, which has been made in view of such points.

### Solution to Problem

The present disclosure is, for example, a MEMS device, including

a first beam and a second beam that are symmetrically disposed with respect to a first rotation axis of a mirror portion, in which

a third beam is disposed on a side opposite to the first beam and the second beam with reference to a line that is orthogonal to the first rotation axis and passes through a center of gravity of the mirror portion.

Further, the present disclosure is, for example, a method of driving a two-axis MEMS device including a mirror portion that twists and vibrates about a first rotation axis at a first vibration frequency and twists and vibrates about a second rotation axis orthogonal to the first rotation axis at a second vibration frequency, comprising:

superimposing a first vibration of an opposite phase and a second vibration of a same phase and inputting the vibrations to each of a first vibration input unit and a second vibration input unit symmetrically disposed with respect to the first rotation axis.

### BRIEF DESCRIPTION OF DRAWINGS

FIG. 1 is a front view of a MEMS device according to an embodiment of the present disclosure.

FIG. 2 is a perspective view (front side) of the MEMS device according to the embodiment of the present disclosure.

FIG. 3 is a perspective view (back side) of the MEMS device according to the embodiment of the present disclosure.

FIG. 4 is a diagram showing a simulation example (high frequency) of the MEMS device according to the embodiment of the present disclosure.

FIG. 5 is a diagram showing a simulation example (low frequency) the MEMS device according to the embodiment of the present disclosure.

FIG. 6 is a diagram showing an example of a method of driving a MEMS device (application voltage) according to the embodiment of the present disclosure.

FIG. 7 is a front view of a MEMS device according to a modified example of the present disclosure.

### MODE(S) FOR CARRYING OUT THE INVENTION

Hereinafter, an embodiment and the like of the present disclosure will be described with reference to the drawings. Note that description will be made in the following order.

### Embodiment

### Modified Example

The embodiment and the like described below are suitable specific examples of the present disclosure, and the content of the present disclosure is not limited to the embodiment and the like.

Note that unless otherwise specified, the dimensions, materials, shapes, and relative arrangements of the constituent members, the direction such as up, down, left, and right, and the like described in the embodiment are not intended to limit the scope of the present disclosure to only them, and are merely examples of description. Note that the size and positional relationship of the members shown in the drawings are exaggerated to clarify the description in some cases, and only part of the reference symbols is illustrated in some cases to prevent the illustration from being complicated.

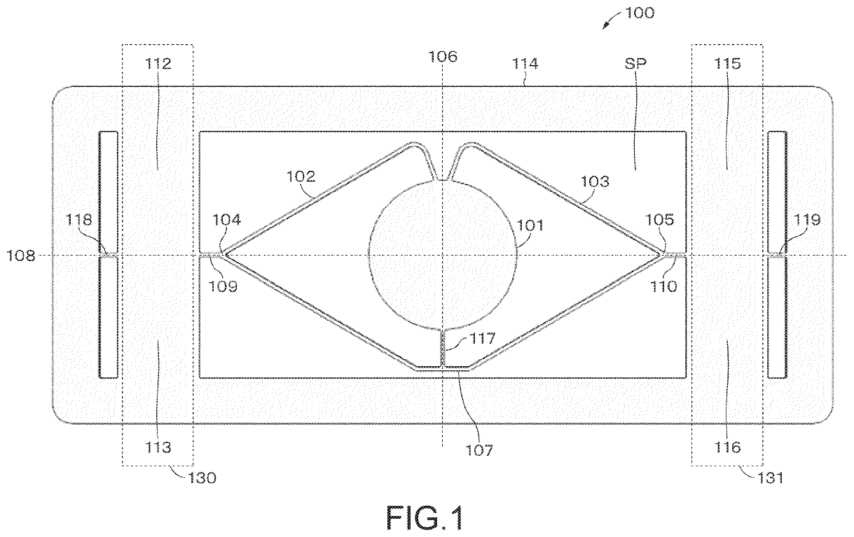

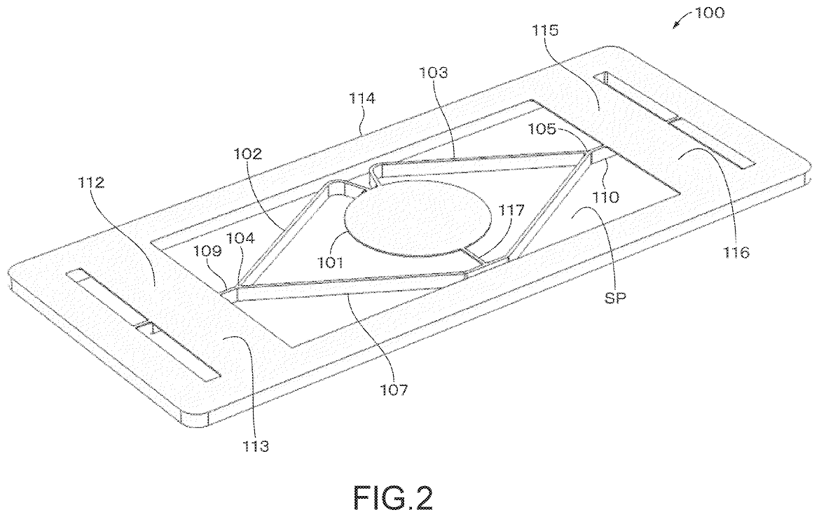

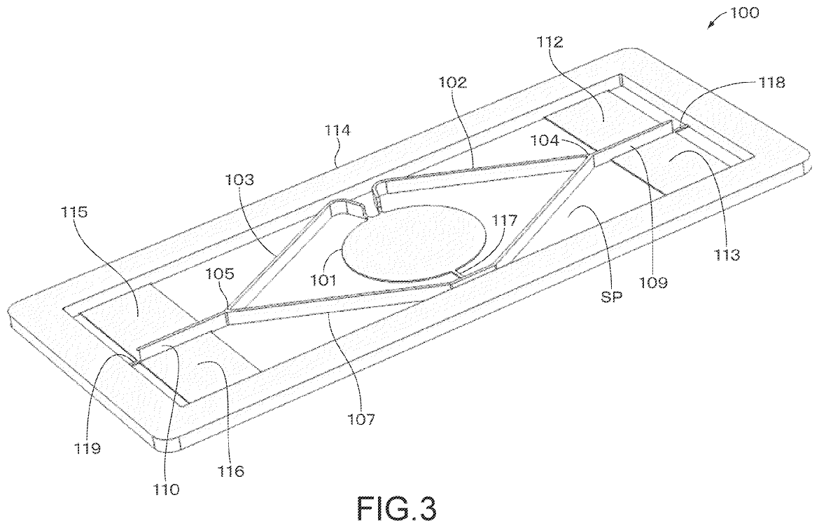

A MEMS device (MEMS device 100) according to an embodiment of the present disclosure will be described with reference to FIG. 1, FIG. 2, and FIG. 3. FIG. 1 is a front view of the MEMS device 100, FIG. 2 is a perspective view of the front side of the MEMS device 100, and FIG. 3 is a perspective view of the back side of the MEMS device 100.

The MEMS device 100 includes, for example, a rectangular frame 114. A rectangular space SP is formed in the vicinity of the center of the frame 114, and a mirror portion 101 having a circular shape is disposed in the vicinity of the center of this space SP. The mirror portion 101 is supported by a first beam 102, a second beam 103, and a third beam 107 that are connected to the mirror portion 101.

The first beam 102 and the second beam 103 are symmetrically disposed with respect to a first rotation axis 106 of the mirror portion 101. The third beam 107 is disposed on the side opposite to the first beam 102 and the second beam 103 with reference to a line that is orthogonal to the first rotation axis 106 and passes through the center of gravity of the mirror portion 101 (opposite side on the first rotation axis 106). Note that since the MEMS device 100 according to this embodiment is a device that performs a two-axis operation, the line that is orthogonal to the first rotation axis 106 and passes through the center of gravity of the mirror portion 101 corresponds to a second rotation axis 108. Note that the MEMS device 100 may be a device that performs one-axis operation.

The first beam 102 extends substantially upward from the portion connected to the mirror portion 101 so as to be away from the first rotation axis 106 and bends from the middle to extend in the direction away from the first rotation axis 106. Then, the tip of the first beam 102 is connected to a first bonding portion 104 provided on the second rotation axis 108.

The second beam 103 extends substantially upward from the portion connected to the mirror portion 101 so as to be away from the first rotation axis 106 and bends from the middle to extend in the direction away from the first rotation axis 106. Then, the tip of the second beam 103 is connected to a second bonding portion 105 provided on the side opposite to the first bonding portion 104 on the second rotation axis 108.

A fourth beam 109 on the second rotation axis 108 is connected to the first bonding portion 104. Further, a fifth beam 110 on the second rotation axis 108 is connected to the second bonding portion 105.

The fourth beam 109 is connected to a first vibration input unit 130 that applies a torsional vibration to the second rotation axis 108 (see FIG. 3). The first vibration input unit 130 includes an upper part 112 of the first vibration input unit 130 and a lower part 113 of the first vibration input unit 130 that are provided at positions symmetrical with respect to the second rotation axis 108. Each of the upper part 112 and the lower part 113 of the first vibration input unit 130 includes a piezoelectric element. The fourth beam 109 is connected to the upper part 112 of the first vibration input unit 130, the lower part 113 of the first vibration input unit 130, and the frame 114.

The fifth beam 110 is connected to a second vibration input unit 131 that applies a torsional vibration to the second rotation axis 108 (see FIG. 3). The second vibration input unit 131 includes an upper part 115 of the second vibration input unit 131 and a lower part 116 of the second vibration input unit 131 that are provided at positions symmetrical with respect to the second rotation axis 108. Each of the upper part 115 and the lower part 116 of the second vibration input unit 131 includes a piezoelectric element. The fifth beam 110 is connected to the upper part 115 of the second vibration input unit 131, the lower part 116 of the second vibration input unit 131, and the frame 114.

A rib is provided in each of part of the first beam 102, part of the second beam 103, part of the third beam 107, part of the fourth beam 109, and part of the fifth beam 110. The rib is a portion protruding to the back surface side than the back surface of the mirror portion 101 and the surface of the piezoelectric element of each vibration input unit in each beam shown in FIG. 3. Note that in the example shown in FIG. 3, each beam and the rib have substantially the same thickness, the thickness may differ. A twist detection sensor 117 serving as a first twist detection unit is provided in the third beam 107 by lamination or the like. A twist detection sensor 118 serving as a second twist detection unit is provided in the fourth beam 109 by lamination or the like. A twist detection sensor 119 serving as a third twist detection unit is provided in the fifth beam 110 by lamination or the like.

Note that the shapes of the first vibration input unit 130 and the second vibration input unit 131 are not limited to the illustrated shapes, they may each include a hinge therein or may be divided into a plurality of parts, and also the occupancy rate of the area is not limited to the illustrated content.

Subsequently, an example of the simulation results will be described. The mirror portion 101 had a circular shape of a diameter of 4 mm, and the size of the frame 114 was set to 9 mm in length and 21 mm in width. The base material was silicon.

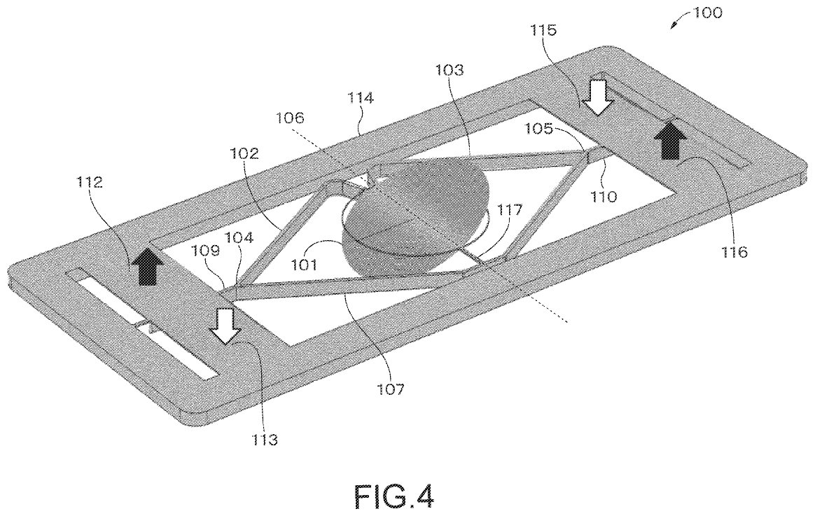

FIG. 4 is diagram showing the simulation result in the case where a vibration of 4.2 kilohertz was applied when the phase of a vibration to be input to the upper part 112 of the first vibration input unit 130 was set to 0 degree, the phase of a vibration to be input to the lower part 113 of the first vibration input unit 130 was set to 180 degrees, the phase of a vibration to be input to the upper part 115 of the second vibration input unit 131 was set to 180 degrees, and the phase of a vibration to be input to the lower part 116 of the second vibration input unit 131 was set to 0 degree. As described above, a vibration of an opposite phase (first vibration) is input to each of the first vibration input unit 130 and the second vibration input unit 131.

It can be seen that a twist is generated at a portion of the first beam 102, which includes a rib extending straight from the first bonding portion 104, and this twist is converted into a twisting operation of the mirror portion 101 at the portion (part) where the first beam 102 bends. Similarly, it can be seen that a twist is generated at a part of the second beam 103, which includes a rib extending straight from the second bonding portion 105, and this twist is converted into a twisting operation of the mirror portion 101 at the portion (part) where the second beam 103 bends. It can be seen that the twist is canceled on the first rotation axis 106 because a twist in the opposite direction is applied from the first bonding portion 104 and the second bonding portion 105 to the third beam 107. As described above, with the configuration according to this embodiment, it is possible to cause a twisting operation about the first rotation axis 106 by the twist input about the second rotation axis 108 orthogonal to the first rotation axis 106. The resonant frequency can be appropriately set by adjusting the thickness and width of the beam, the end position of the rib on the mirror side and the frame side, the presence or absence of connection between the frame and the rib, the interval between the first beam 102 and the second beam 103, and the like.

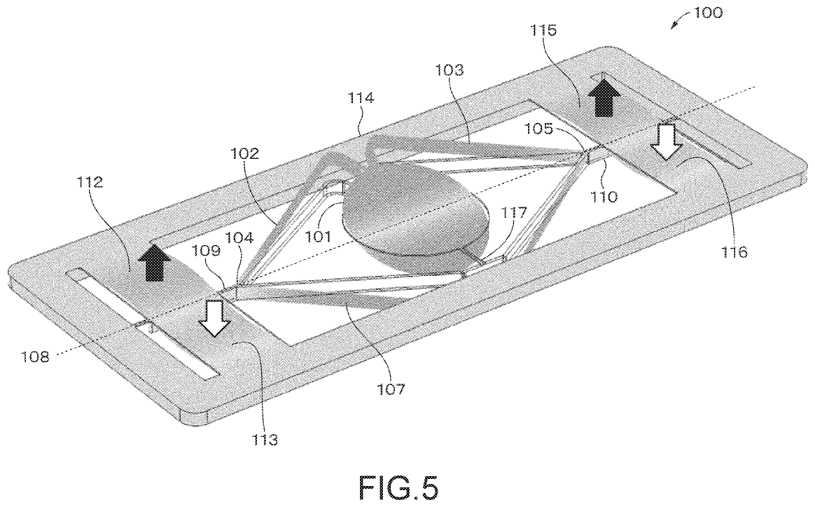

FIG. 5 is a simulation result in the case where a vibration was applied when the phase of a vibration to be input to the upper part 112 of the first vibration input unit 130 was set to 0 degree, the phase of a vibration to be input to the lower part 113 of the first vibration input unit 130 was set to 180 degrees, the phase of a vibration to be input to the upper part 115 of the second vibration input unit 131 was set to 0 degree, and the phase of a vibration to be input to the lower part 116 of the second vibration input unit 131 was set to 180 degrees. As described above, a vibration of the same phase (second vibration) is input to each of the first vibration input unit 130 and the second vibration input unit 131. The mirror portion 101 performs a twisting operation about the second rotation axis 108.

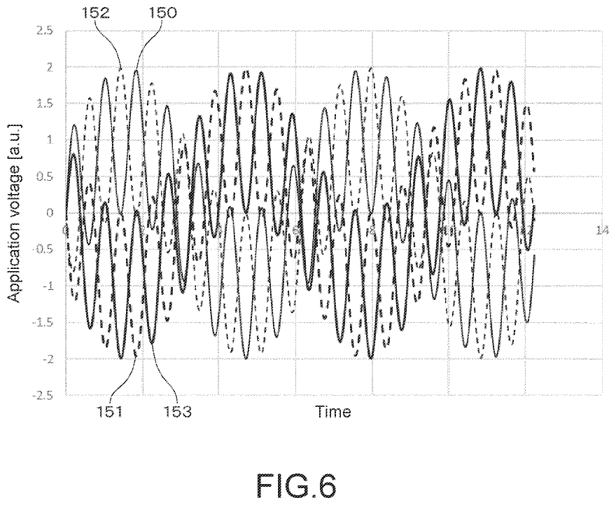

FIG. 6 shows an example of a voltage applied to a piezoelectric element of each vibration input unit. In FIG. 6, the horizontal axis represents time and the vertical axis represents the application voltage. Note that the value of the application voltage is shown as an arbitrary unit (a.u.) normalized using a predetermined reference value. Further, in FIG. 6, a waveform denoted by a reference symbol 150 represents an application voltage waveform to the upper part 112 of the first vibration input unit 130, a waveform denoted by a reference symbol 151 represents an application voltage waveform to the lower part 113 of the first vibration input unit 130, a waveform denoted by a reference symbol 152 represents an application voltage waveform to the upper part 115 of the second vibration input unit 131, and a waveform denoted by a reference symbol 153 represents an application voltage waveform to the lower part 116 of the second vibration input unit 131.

As described above, by appropriately changing the phases of a vibration to be input to the first vibration input unit 130 and a vibration to be input to the second vibration input unit 131, it is possible to generate a twisting operation based on a first vibration frequency about the first rotation axis 106 and a twisting operation based on a second vibration frequency about the second rotation axis 108. Specifically, by superimposing a vibration of an opposite phase and a vibration of the same phase and inputting the vibrations to each of the first vibration input unit 130 and the second vibration input unit 131, it is possible to simultaneously generate a two-axis twisting operation.

Therefore, it is possible to reduce the dead space while maintaining or improving the figure of merit as compared with the existing two-axis scanning type MEMS mirror. The torsional vibration about the second rotation axis 108 can operate in resonance or non-resonance. The twist detection sensor includes a piezoelectric element or the like, and the application voltage of the piezoelectric element of each of the first vibration input unit 130 and the second vibration input unit 131 is controlled on the basis of the frequency and intensity of the electrical signal obtained from the sensor. Note that it is not necessarily need to provide the twist detection sensor 117 of the third beam 107, and high frequency components of electrical signals obtained from the twist detection sensors 118 and 119 of the fourth beam 109 and the fifth beam 110 may be used as a substitute.

The MEMS device 100 according to this embodiment can be produced using, for example, an SOI (Silicon on Insulator) substrate. An insulation layer, a lower electrode layer, a piezoelectric element, and an upper electrode layer are deposited on the laminated silicon surface. After removing the silicon substrate of SOI of a region excluding a frame portion and a rib portion up to an SiO₂ layer by selective dry etching, the SiO₂ layer of the same region is removed. The piezoelectric element and the upper electrode layer other than a vibration input unit and a twist detection unit are removed by dry etching from the surface layer, and the lower electrode layer is removed leaving a piezoelectric element region and a wiring region. After that, a metal film for wiring of the upper electrode is deposited, and a reflective film is deposited on a mirror surface of the surface layer. Next, the silicon layer and the SiO₂ layer other than necessary parts such as a frame, a mirror, a beam, and a vibration input unit are removed. Further, as necessary, a reflective film is provided on the back surface of the mirror and a metal film is provided on the back surface of the frame. There may be a metal wiring for taking out on the frame surface, and there may be a metal film therearound. The metal films on the front and back of the frame can be used when bonding to a support casing. The mirror reflective film may be covered with gold, silver, aluminum, or a dielectric film thereof, or may be a dielectric multilayer film. In order to suppress the warp of the mirror surface, it is favorable that the reflective films on the front and back have the same layer configuration. These are examples, and various methods that are general as MEMS processes can be used for the production process. The cross section of the rib portion does not necessarily need to be rectangular, and may be a tapered shape or a reverse tapered shape. The rib may be laminated on the silicon surface.

### Modified Example

Although the embodiment of the present disclosure has been specifically described above, the content of the present disclosure is not limited to the embodiment described above, and various modifications based on the technical idea of the present disclosure can be made.

The structure of the MEMS device 100 shown in FIG. 1 is an example, and can be modified to the extent that the effect in the present disclosure can be expected. For example, the mirror portion 101 does not necessarily need to have a circular shape, and an elliptical shape, a square shape, a rhombic shape, a polygonal shape, or the like can be applied. Further, a rib may be provided on the back surface of the mirror portion 101. The rib makes it possible to suppress the bending of the mirror portion 101. Each dimension and ratio of each configuration may be changed. For example, by increasing the lengths of the fourth beam 109 and the fifth beam 110 with respect to the lengths of the first beam 102, the second beam 103, and the third beam 107, it is possible to increase the torsional vibration about the second rotation axis 108. By increasing the sizes of the first vibration input unit 130 and the second vibration input unit 131 within an allowable range in the application, it is possible to input a larger amount of energy.

The material of the MEMS device 100 is not limited to silicon, may be a metal, ceramic, or the like, and a production method (e.g., pulse laser processing) corresponding to these materials may be applied. It is known that the processing mode of the pulse laser processing differs depending on the pulse width such as a femtosecond region, a picosecond region, and a nanosecond region of a laser, and an appropriate method can be used in accordance with the processing portion.

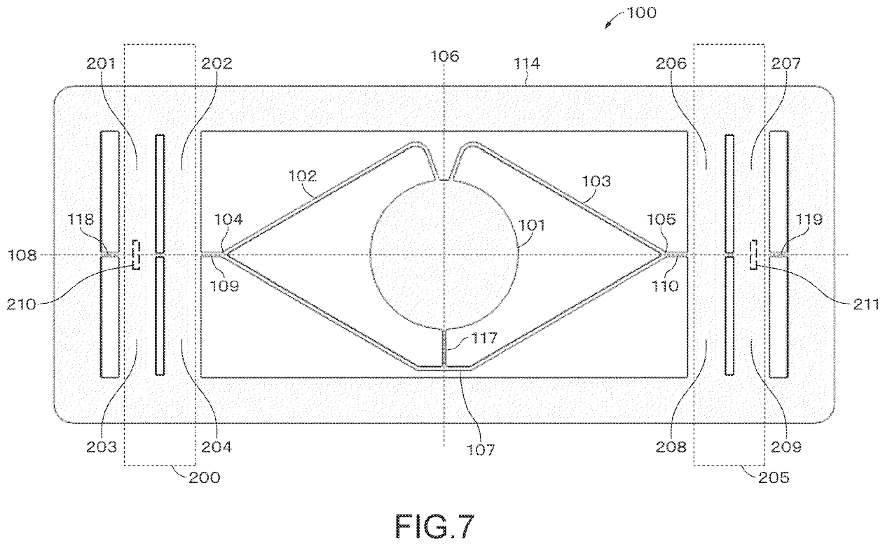

In order to more positively excite the torsional vibration of a high frequency, a first vibration input unit 200 and a second vibration input unit 205 as shown in FIG. 7 can be used. The first vibration input unit 200 is divided into an upper outer vibration input unit 201, an upper inner vibration input unit 202, a lower outer vibration input unit 203, and a lower inner vibration input unit 204. Similarly, the second vibration input unit 205 is divided into an upper inner vibration input unit 206, an upper outer vibration input unit 207, a lower inner vibration input unit 208, and a lower outer vibration input unit 209. A cross rib 210 is provided in the first vibration input unit 200 so as to staddle the upper outer vibration input unit 201 and the lower outer vibration input unit 203. Further, a cross rib 211 is provided in the second vibration input unit 205 so as to staddle the upper outer vibration input unit 207 and the lower outer vibration input unit 209.

In order to excite the torsional vibration about the first rotation axis 106 of the mirror portion 101, in the case where the phase of a vibration to be input (applied) to the upper outer vibration input unit 201 of the first vibration input unit 200 is set to 0 degree, the phase of a vibration to be input to the upper inner vibration input unit 202 is set to 180 degrees, the phase of a vibration to be input to the upper inner vibration input unit 206 is set to 0 degree, the phase of a vibration to be input to the upper outer vibration input unit 207 is set to 180 degrees, the phase of a vibration to be input to the lower outer vibration input unit 203 is set to 180 degrees, the phase of a vibration to be input to the lower inner vibration input unit 204 is set to 0 degree, the phase of a vibration to be input to the lower inner vibration input unit 208 is set to 180 degrees, and the phase of a vibration to be input to the lower outer vibration input unit 209 is set to 0 degree. As a result, a torsional vibration is generated in the first beam 102 and the second beam 103.

Note that in order to excite the torsional vibration about the second rotation axis 108 of the mirror portion 101, in the case where the phase to be input to the upper outer vibration input unit 201 of the first vibration input unit 200 is set to 0 degree, the phase of a vibration to be input to the upper inner vibration input unit 202 is set to 0 degree, the phase of a vibration to be input to the upper inner vibration input unit 206 is set to 0 degree, the phase of a vibration to be input to the upper outer vibration input unit 207 is set to 0 degree, the phase of a vibration to be input to the lower outer vibration input unit 203 is set to 180 degrees, the phase of a vibration to be input to the lower inner vibration input unit 204 is set to 180 degrees, the phase of a vibration to be input to the lower inner vibration input unit 208 is set to 180 degrees, and the phase of a vibration to be input to the lower outer vibration input unit 209 is set to 180 degrees. In order to perform a two-axis operation of the mirror, the above-mentioned first vibration for exciting the torsional vibration about the first rotation axis 106 and the second vibration for exciting the torsional vibration about the second rotation axis 108 are superimposed and applied. Further, in order to separately excite the torsional vibration of a high frequency about the first rotation axis 106 and the torsional vibration of a low frequency about the second rotation axis 108, the piezoelectric element may be divided.

The configurations, methods, processes, shapes, materials, numerical values, and the like given in the above-mentioned embodiment and modified example are merely examples and may be replaced with known ones, and configurations, methods, processes, shapes, materials, numerical values, and the like different from these may be used as necessary. Further, the configurations, methods, processes, shapes, materials, numerical values, and the like in the embodiment and modified example can be combined with each other as long as there is no technical contradiction.

It should be noted that the content of the present disclosure is not limitedly interpreted by the effects illustrated in the present specification.

The present disclosure may also take the following configurations.

(1) A MEMS device, including:

a first beam and a second beam that are symmetrically disposed with respect to a first rotation axis of a mirror portion, in which

a third beam is disposed on a side opposite to the first beam and the second beam with reference to a line that is orthogonal to the first rotation axis and passes through a center of gravity of the mirror portion.

(2) The MEMS device according to (1), in which

the first beam extends while bending in a direction away from the first rotation axis, a tip of the first beam being connected to a first bonding portion, and

the second beam extends while bending in a direction away from the first rotation axis, a tip of the second beam being connected to a second bonding portion, the MEMS device further including:

a fourth beam that extends from the first bonding portion in a direction away from the first rotation axis; and

a fifth beam that extends from the second bonding portion in a direction away from the first rotation axis.

(3) The MEMS device according to (2), in which

a first vibration input unit that applies a torsional vibration to a second rotation axis orthogonal to the first rotation axis is connected to the fourth beam, and

a second vibration input unit that applies a torsional vibration to the second rotation axis is connected to the fifth beam.

(4) The MEMS device according to (3), in which

a first vibration of an opposite phase and a second vibration of a same phase are superimposed and input to each of the first vibration input unit and the second vibration input unit.

(5) The MEMS device according to (4), in which

the mirror portion twists and vibrates about the first rotation axis at a first vibration frequency by inputting the first vibration to each of the first vibration input unit and the second vibration input unit, and

the mirror portion twists and vibrates about the second rotation axis at a second vibration frequency by inputting the second vibration to each of the first vibration input unit and the second vibration input unit.

(6) The MEMS device according to any one of (3) to (5), in which

each of the first vibration input unit and the second vibration input unit includes a piezoelectric element.

(7) The MEMS device according to any one of (1) to (6), in which

a first twist detection unit is provided in the third beam.

(8) The MEMS device according to any one of (2) to (6), in which

a second twist detection unit is provided in the fourth beam, and a third twist detection unit is provided in the fifth beam.

(9) A method of driving a two-axis MEMS device including a mirror portion that twists and vibrates about a first rotation axis at a first vibration frequency and twists and vibrates about a second rotation axis orthogonal to the first rotation axis at a second vibration frequency, including:

superimposing a first vibration of an opposite phase and a second vibration of a same phase and inputting the vibrations to each of a first vibration input unit and a second vibration input unit symmetrically disposed with respect to the first rotation axis.

### REFERENCE SIGNS LIST

100: MEMS device
101: mirror portion
102: first beam
103: second beam
104: first bonding portion
105: second bonding portion
107: third beam
108: second rotation axis
109: fourth beam
110: fifth beam
112: upper part of first vibration input unit
113: lower part of first vibration input unit
115: upper part of second vibration input unit
116: lower part of second vibration input unit
117: first twist detection sensor
118: second twist detection sensor
119: third twist detection sensor
200: first vibration input unit
201: upper outer vibration input unit of first vibration input unit
202: upper inner vibration input unit of first vibration input unit
203: lower outer vibration input unit of first vibration input unit
204: lower inner vibration input unit of first vibration input unit
205: second vibration input unit
206: upper inner vibration input unit of second vibration input unit
207: upper outer vibration input unit of second vibration input unit
208: lower inner vibration input unit of second vibration input unit
209: lower outer vibration input unit of second vibration input unit

1. A MEMS device, comprising:
a first beam and a second beam that are symmetrically disposed with respect to a first rotation axis of a mirror portion, wherein
a third beam is disposed on a side opposite to the first beam and the second beam with reference to a line that is orthogonal to the first rotation axis and passes through a center of gravity of the mirror portion.

2. The MEMS device according to claim 1, wherein
the first beam extends while bending in a direction away from the first rotation axis, a tip of the first beam being connected to a first bonding portion, and
the second beam extends while bending in a direction away from the first rotation axis, a tip of the second beam being connected to a second bonding portion, the MEMS device further comprising:
a fourth beam that extends from the first bonding portion in a direction away from the first rotation axis; and
a fifth beam that extends from the second bonding portion in a direction away from the first rotation axis.

3. The MEMS device according to claim 2, wherein
a first vibration input unit that applies a torsional vibration to a second rotation axis orthogonal to the first rotation axis is connected to the fourth beam, and
a second vibration input unit that applies a torsional vibration to the second rotation axis is connected to the fifth beam.

4. The MEMS device according to claim 3, wherein
a first vibration of an opposite phase and a second vibration of a same phase are superimposed and input to each of the first vibration input unit and the second vibration input unit.

5. The MEMS device according to claim 4, wherein
the mirror portion twists and vibrates about the first rotation axis at a first vibration frequency by inputting the first vibration to each of the first vibration input unit and the second vibration input unit, and
the mirror portion twists and vibrates about the second rotation axis at a second vibration frequency by inputting the second vibration to each of the first vibration input unit and the second vibration input unit.

6. The MEMS device according to claim 3, wherein
each of the first vibration input unit and the second vibration input unit includes a piezoelectric element.

7. The MEMS device according to claim 1, wherein
a first twist detection unit is provided in the third beam.

8. The MEMS device according to claim 2, wherein
a second twist detection unit is provided in the fourth beam, and a third twist detection unit is provided in the fifth beam.

9. A method of driving a two-axis MEMS device including a mirror portion that twists and vibrates about a first rotation axis at a first vibration frequency and twists and vibrates about a second rotation axis orthogonal to the first rotation axis at a second vibration frequency, comprising:
superimposing a first vibration of an opposite phase and a second vibration of a same phase and inputting the vibrations to each of a first vibration input unit and a second vibration input unit symmetrically disposed with respect to the first rotation axis.
